(19) United States
(12) Patent Application Publication
(10) Pub. No.: US 2013/0001707 A1
(43) Pub. Date: Jan. 3, 2013

(54) FABRICATING METHOD OF MOS TRANSISTOR, FIN FIELD-EFFECT TRANSISTOR AND FABRICATION METHOD THEREOF

(76) Inventors: Chien-Liang Lin, Taoyuan County (TW); Ying-Wei Yen, Miaoli County (TW); Yu-Ren Wang, Tainan City (TW); Chan-Lon Yang, Taipei City (TW); Chin-Cheng Chien, Tainan City (TW); Chun-Yuan Wu, Yunlin County (TW); Chih-Chien Liu, Taipei City (TW); Chin-Fu Lin, Tainan City (TW); Teng-Chun Tsai, Tainan City (TW)

(21) Appl. No.: 13/174,711

(22) Filed: Jun. 30, 2011

(51) Int. Cl. H01L 29/78; H01L 21/31

(52) U.S. Cl. 257/410; 438/785; 257/E21.24; 257/E29.255

(57) ABSTRACT

A fabricating method of a MOS transistor includes the following steps. A substrate is provided. A gate dielectric layer is formed on the substrate. A nitridation process containing nitrogen plasma and helium gas is performed to nitride the gate dielectric layer. A fin field-effect transistor and fabrication method thereof are also provided.

### BACKGROUND OF THE INVENTION

1. Field of the Invention

The present invention relates generally to a fabricating method of a MOS transistor and a FinFET, and more specifically, to a fabricating method of a MOS transistor, a FinFET and a fabrication method thereof applying a nitrogen plasma and helium gas nitridation process.

2. Description of the Prior Art

In a conventional transistor process, the dielectric constant of the gate dielectric layer is enhanced and the performance of the gate dielectric layer is improved by performing a nitridation process to nitride the gate dielectric layer. In general, the degree of improvement of the gate dielectric layer performance is directly proportional to the nitridation concentration. In current processes, the nitridation concentration can be enhanced by increasing the power of nitrogen plasma generation or increasing the nitridation process time; however, there is an upper limit to the power of nitrogen plasma generation and increasing the nitridation process time will reduce the process efficiency. Furthermore, the nitrogen tends to diffuse downwards in the substrate as more nitrogen is distributed in the interface between the substrate and the gate dielectric layer, so the carrier mobility of the gate channel as well as the electrical performance will be reduced.

If the transistor is a FinFET, its substrate would have at least a fin-shaped structure with a gate dielectric layer covering each structure, so the gate dielectric layer of the FinFET can be described as a gate dielectric layer having a [symbol] shaped profile. When the nitridation process is performed to nitride the gate dielectric layer, the complicated structure of the gate dielectric layer means that the nitridation of the gate dielectric layer will not be uniform.

### SUMMARY OF THE INVENTION

The present invention therefore provides fabricating methods of a MOS transistor and a FinFET, capable of enhancing the nitridation concentration of the gate dielectric layer and solving the problems of nitrogen diffusing downwards in the substrate and the non-uniform distribution of nitrogen in the gate dielectric layer.

The present invention provides a fabricating method of a MOS transistor. A substrate is provided. A gate dielectric layer is formed on the substrate. A nitrogen plasma and helium gas containing nitridation process is performed to nitride the gate dielectric layer.

The present invention provides a fabricating method of a FinFET. A substrate comprising at least a fin-shaped structure is provided. A gate dielectric layer having a [symbol] shaped profile is formed on the fin-shaped structure. A nitrogen plasma and helium gas containing nitridation process is performed to nitride the gate dielectric layer having a [symbol] shaped profile.

The present invention further provides a FinFET structure comprising a substrate and a gate dielectric layer having a [symbol] shaped profile. The substrate has at least a fin-shaped structure. The gate dielectric layer having a [symbol] shaped profile is located on the fin-shaped structure, wherein the gate dielectric layer having a [symbol] shaped profile comprises one horizontal portion and two vertical portions, and the nitridation concentration difference between the horizontal portion and the vertical portions is less than 3%.

According to the above, the present invention provides a fabricating method of a MOS transistor, and a FinFET structure and fabrication method thereof, wherein the surface of the gate dielectric layer is nitrided uniformly with a high concentration by performing a nitrogen plasma and helium gas containing nitridation process. In this way, taking the FinFET as an example, the nitridation concentration difference between the horizontal portion and the vertical portions of the FinFET formed by the methods of the present invention can be less than 3%, such that the horizontal portion and the vertical portions can substantially have the same nitridation concentration, thereby solving the problem of the non-uniformity in nitridation concentration of the horizontal portion and the vertical portions of a FinFET.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 schematically depict a cross-sectional view of a fabricating method of a MOS transistor according to one embodiment of the present invention.

FIGS. 3-6 schematically depict a top view of a fabricating method of a FinFET according to one embodiment of the present invention.

FIG. 7 schematically depicts a cross-sectional view along the line AA' of the FinFET of FIG. 6.

FIG. 8 schematically depicts a cross-sectional view of a plasma nitridation device according to one embodiment of the present invention.

FIG. 9 schematically depicts a cross-sectional view of a portion of the plasma nitridation device of FIG. 8.

FIG. 10 schematically depicts a cross-sectional view of a fabricating method of a MOS transistor according to one embodiment of the present invention.

### DETAILED DESCRIPTION

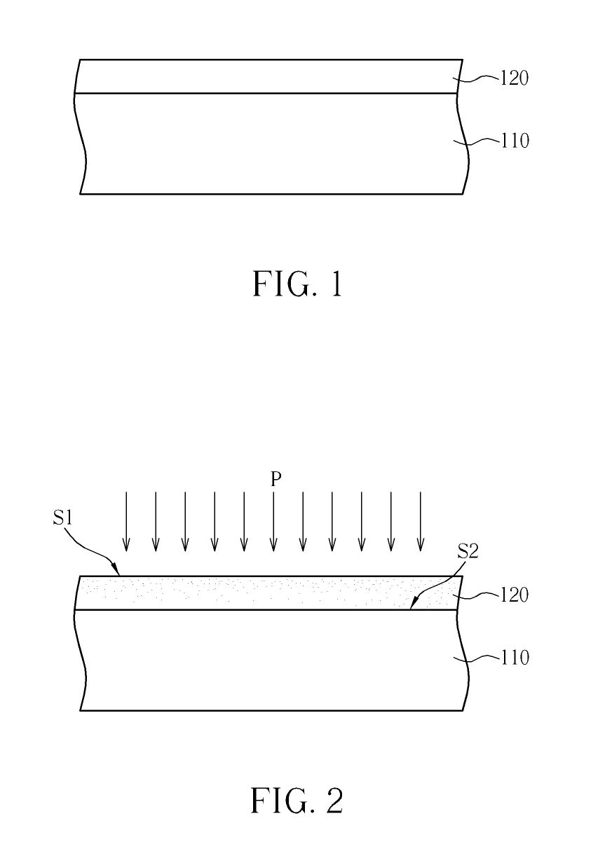

FIGS. 1-2 schematically depict a cross-sectional view of a fabricating method of a MOS transistor according to one embodiment of the present invention. Please refer to FIGS. 1-2. As shown in FIG. 1, a substrate 110 is provided. A gate dielectric layer 120 is formed on the substrate 110. The substrate 110 may be a semiconductor substrate such as a silicon substrate, a silicon-containing substrate or a silicon-on-insulator (SOI) substrate. In one embodiment, the gate dielectric layer 120 may be a silicon dioxide layer, formed by performing an oxidation process on the silicon substrate 110. In anther embodiment, the gate dielectric layer 120 may be a dielectric layer having a high dielectric constant. An interfacial layer (not shown) may be selectively formed between the dielectric layer having a high dielectric constant and the substrate 110 for buffering the dielectric layer having a high dielectric constant and the substrate 110, wherein the dielectric layer having a high dielectric constant may be a hafnium oxide layer, but is not limited thereto.

As shown in FIG. 2, a nitrogen plasma and helium gas containing nitridation process P is performed to nitride the gate dielectric layer 120. After the gate dielectric layer 120 is nitrided, at least a portion of the gate dielectric layer 120 transforms to an oxy-nitride layer as the gate dielectric layer 120 is a silicon dioxide layer and at least a portion of the gate dielectric layer 120 transforms to a HfSiON layer as the gate dielectric layer 120 is a hafnium oxide layer. The performance and the dielectric constant of the gate dielectric layer 120 are both enhanced.

It should be noted that the nitridation process P of the present invention contains nitrogen plasma and helium gas. Helium gas is used as an auxiliary gas for helping nitrogen gas dissociate to nitrogen plasma. This means the nitrogen plasma and helium gas containing nitridation process P has a higher dissociation rate than the nitridation process of the prior art, which only imports nitrogen, leading to a higher nitridation concentration of the gate dielectric layer. In this embodiment, the nitridation process P is a decoupled plasma nitridation process, but in another embodiment the nitridation process P may be remote plasma nitridation process. For example, the processing steps of the nitridation process P may be as follows. Nitrogen gas is firstly imported into a chamber, and then the nitrogen gas is dissociated into nitrogen plasma according to a voltage difference between a positive electrode and a negative electrode, so that the gate dielectric layer 120 can be nitrided. Because the decoupled plasma nitridation process only nitrides the upper surface S1 of the gate dielectric layer 120, the prior art problem of nitrogen diffusing downwards in the substrate 110 and reducing the carrier mobility of the gate channel due to large amounts of nitrogen gas distributing on the lower surface S2 of the gate dielectric layer 120 that contacts the substrate 110 is solved.

When the proportion of helium gas is higher, the capability of assisting nitrogen-dissociating is enhanced, so that the dissociation rate of nitrogen is increased and the nitridation concentration of the gate dielectric layer is increased. When the proportion of helium gas is too high, however, the gate dielectric layer 120 will be damaged due to helium gas striking the upper surface S1 of the gate dielectric layer 120. Therefore, the pressure ratio of nitrogen gas/helium gas imported during the nitridation process of the present invention will not be less than 5. In a preferred embodiment, the pressure ratio of the nitrogen gas and the helium gas imported during the nitridation process is 5:1. In a still preferred embodiment, the pressure ratio of the nitrogen gas and the helium gas imported during the nitridation process is 10:1.

The total pressure of the gas imported during the nitridation process P of the present invention is much higher than in the prior art, which may be 5 mT˜20 mT. In a preferred embodiment, the total pressure of the gas imported during the decoupled plasma nitridation process is about 50 mT˜150 mT. In a still preferred embodiment, the total pressure of the gas imported during the decoupled plasma nitridation process is about 80 mT˜100 mT. The reason is that: as the total pressure of gas (wherein the gas in the present invention at least includes nitrogen and helium gas) is higher, the nitrogen distribution of the gate dielectric layer 120 is more uniform. Apart from importing helium gas to increase the nitridation concentration of the top surface S1 of the gate dielectric layer 120, the nitridation uniformity of the gate dielectric layer 120 can also be enhanced by increasing the total pressure of the imported gas.

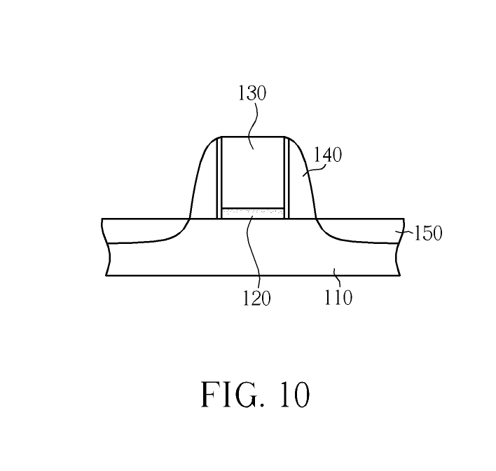

After the gate dielectric layer 120 is formed, sequential processes can be performed for completing the fabrication of the MOS transistor. As shown in FIG. 10, the sequential processes may be: forming a gate electrode layer 130, a spacer 140, or a source/drain region 150 etc. Additionally, the sequential processes may include a MOS transistor undergoing a poly-silicon gate process or a MOS transistor undergoing a metal gate process, such as a gate first process or a gate last process etc. Otherwise, the transistor of the present invention may still include other semiconductor structures (not shown) such as a metal silicide located on the source/drain region, an epitaxial layer composed of silicon and other materials located on the source/drain region, or other protective layers formed by etching back a silicon substrate paired with a selective epitaxial growth (SEG) process. In an embodiment, after the source/drain region or the metal silicide (not shown) is formed, a portion or a whole spacer may be further removed to form a contact etch stop layer (CESL) having a suitable stress corresponding to the transistor, wherein the material of the contact etch stop layer may be silicon nitride. Otherwise, this embodiment sequentially forms a lightly doped source/drain region, a spacer and a source/drain region, but is not limited thereto. The order of the above forming steps can also be changed in accordance with practical process demands.

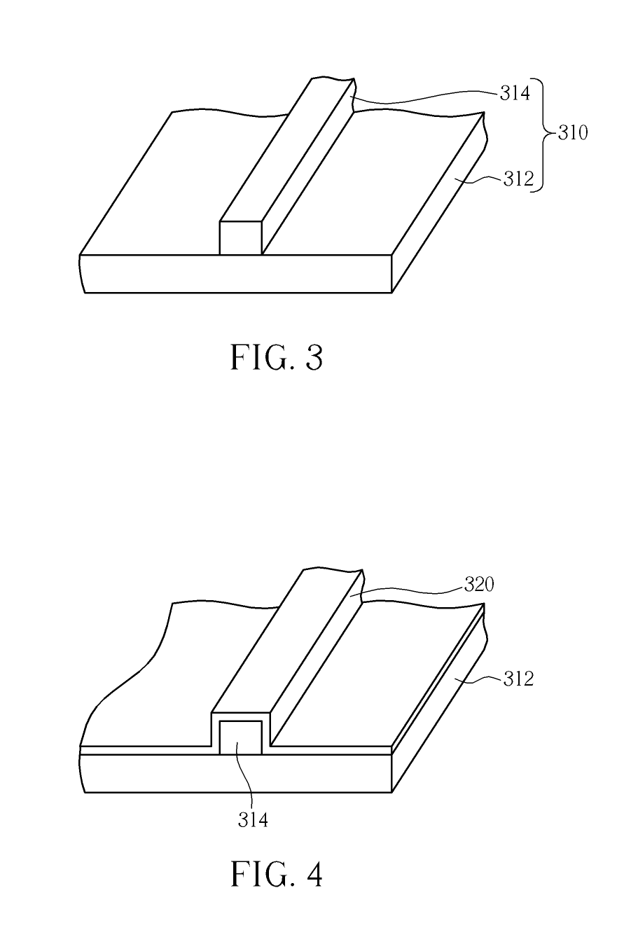

FIGS. 3-6 schematically depict a top view of a fabricating method of a FinFET according to one embodiment of the present invention. Please refer to FIGS. 3-6. As shown in FIG. 3, a substrate 310 is provided. The substrate 310 includes a body 312 and at least a fin-shaped structure 314 located on the body 312. For example, the forming methods of the substrate 310 may include the following steps. A silicon substrate is provided. A mask layer is formed on the silicon substrate. The mask layer may be an oxide layer formed by a thermal oxidation process. A photoresist layer is formed on the mask layer. A lithography and etching process is performed to remove a portion of the mask layer and form a patterned mask layer covering a predetermined area desired to form a fin-shaped structure. The silicon substrate is etched by using the patterned mask layer as an etching mask to form a fin-shaped structure 314 on the body 312. There are other possible methods for forming the substrate 310 having the fin-shaped structure 314 thereon: for instance, etching a single crystalline layer on the silicon-on-insulator to form a substrate having a fin-shaped structure.

As shown in FIG. 4, a gate dielectric layer 320 having a [symbol] shaped profile is formed on the fin-shaped structure 314. In one case, the gate dielectric layer 320 may be a silicon dioxide layer. In another case, the gate dielectric layer 320 may be a dielectric layer having a high dielectric constant and an interlayer (not shown) may be formed between the substrate 310 and the gate dielectric layer 320 for buffering the dielectric layer having a high dielectric constant and the substrate 310, wherein the dielectric layer having a high dielectric constant may be a hafnium oxide layer, but is not limited thereto. As shown in FIG. 5, a nitrogen plasma and helium gas containing nitridation process P is performed to nitride the gate dielectric layer having a [symbol] shaped profile 320. After the gate dielectric layer 320 is nitrided, at least a portion of the gate dielectric layer 320 will transform to an oxy-nitride layer as the gate dielectric layer 320 is a silicon dioxide layer, and at least a portion of the gate dielectric layer 320 will transform to an HfSiON layer as the gate dielectric layer 320 is a hafnium oxide layer. In this way, the dielectric constant and the electrical performance of the gate dielectric layer 320 can be improved.

It should be noted that the nitridation process P of the present invention contains nitrogen plasma and helium gas. Helium gas is used as an auxiliary gas for helping nitrogen gas dissociate to nitrogen plasma. This means the nitrogen plasma and helium gas containing nitridation process P has a higher dissociation rate than the nitridation process of the prior art, which only imports nitrogen, leading to a higher nitridation concentration of the gate dielectric layer. In this embodiment, the nitridation process P is a decoupled plasma nitridation process, but in another embodiment the nitridation process P may be remote plasma nitridation process. Because the decoupled plasma nitridation process just nitrides the external surface S3 of the gate dielectric layer 320, the prior art problem of nitrogen diffusing inwards in the fin-shaped structure 314 and reducing the carrier mobility of the gate channel caused by large amounts of nitrogen gas distributing in the inner surface S4 of the gate dielectric layer 320 that contacts the fin-shaped structure 314 is solved.

When the proportion of helium gas is higher, the capability of assisting nitrogen-dissociating is enhanced, so that the dissociation ratio of nitrogen is enhanced and the nitridation concentration of the gate dielectric layer is increased. When the proportion of helium gas is too high, however, the gate dielectric layer 320 will be damaged due to helium gas striking the external surface S3 of the gate dielectric layer 320. Therefore, the pressure ratio of nitrogen gas/helium gas imported during the nitridation process of the present invention is not less than 5. In a preferred embodiment, the pressure ratio of the nitrogen gas and the helium gas imported during the nitridation process is 5:1. In a still preferred embodiment, the pressure ratio of the nitrogen gas and the helium gas imported during the nitridation process is 10:1.

After the gate dielectric layer 320 is nitrided, various sequential processes can be performed to complete the manufacturing of the FinFET. As shown in FIG. 6, a gate electrode (not shown) is formed on the gate dielectric layer 320. Then, the gate electrode and the gate dielectric layer 320 are etched to form a gate structure 330, including a gate dielectric layer 320′ and a gate electrode 332, almost normal to the fin-shaped structure 314. Thereafter, sequential processes such as forming a spacer, forming a source/drain region etc. may be performed.

As shown in FIG. 6, a FinFET 300 including a substrate 310 and a gate dielectric layer having a [symbol] shaped profile 320′ is formed according to the methods of the present invention. The substrate 310 includes a body 312 and at least a fin-shaped structure 314 located on the body 312. The gate dielectric layer having a [symbol] shaped profile 320′ is located on the fin-shaped structure 314. The gate dielectric layer 320′ includes a transition layer 322 located on an external surface S3 of a body 324, wherein the transition layer 322 is transformed from the body 324 by performing the nitridation process P. For example, when the body 324 is a silicon dioxide layer, the transition layer 322 is an oxynitride layer located on the external surface S3 of the silicon dioxide layer; when the body 324 is a hafnium oxide layer, the transition layer 322 is an HfSiON layer located on the external surface S3 of the hafnium oxide layer.

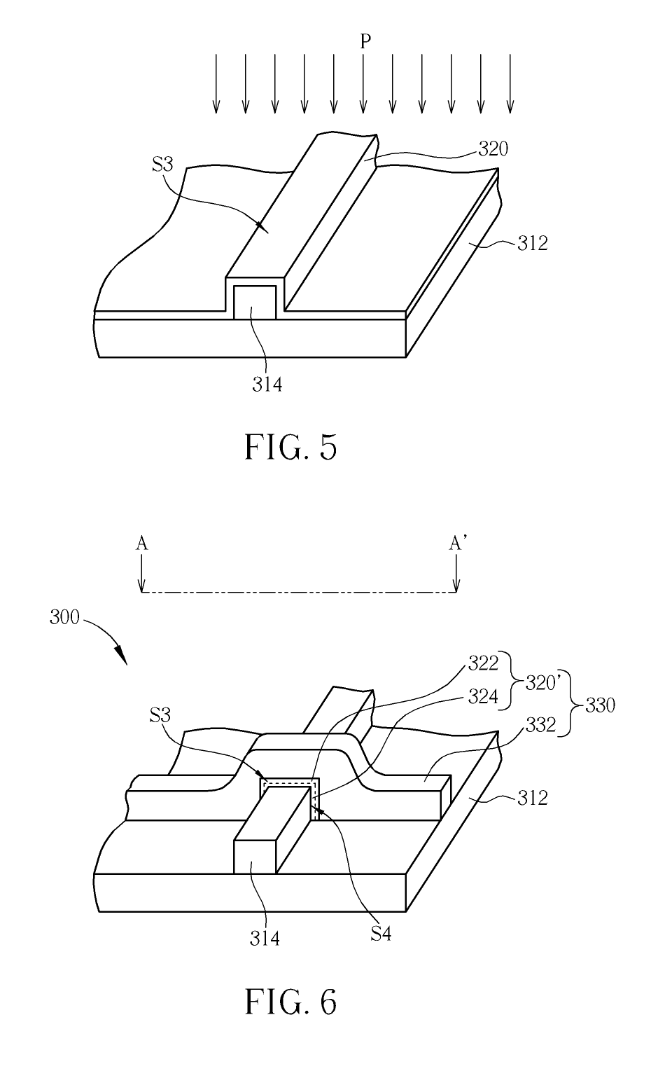

FIG. 7 schematically depicts a cross-sectional view along the line AA' of the FinFET of FIG. 6. As shown in FIG. 7, the gate dielectric layer having a [symbol] shaped profile 320′ includes one horizontal portion h and two vertical portions v1 and v2. The total pressure of the gas imported during the nitridation process P of the present invention is much higher than in the prior art, so that the nitridation concentration of the gate dielectric layer 320′ is more uniform than in the prior art. Therefore, the nitridation concentration difference between the horizontal portion h and the vertical portions v1 and v2 of the present invention can be less than 3%. In a preferred embodiment, the nitridation concentration of the horizontal portion h and the vertical portions v1 and v2 is substantially the same. In a preferred embodiment, the total pressure of the gas imported during the decoupled plasma nitridation process is about 50 mT˜150 mT. In a still preferred embodiment, the total pressure of the gas imported during the decoupled plasma nitridation process is about 80 mT˜100 mT.

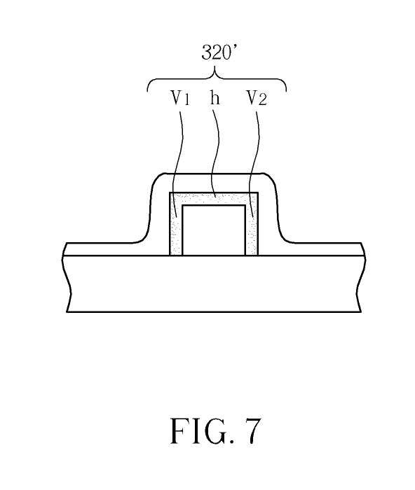

The present invention also provides a magnetic device to further improve the uniformity of nitridation concentration of the plasma nitridation process. FIG. 8 schematically depicts a cross-sectional view of a plasma nitridation device according to one embodiment of the present invention. As shown in FIG. 8, the aforesaid FinFET 300 can be inputted into a plasma nitridation device 400. The plasma nitridation device 400 nitrides the gate dielectric layer 320 of the FinFET 300 by dissociating nitrogen gas into the nitrogen plasma 430 by respectively forcing an upper electrode 410 and a lower electrode 420 with a positive voltage and a negative voltage. Specifically, the plasma nitridation device 400 of the present invention includes a magnetic device 440 used for changing the distributing position of the nitrogen plasma 430, thereby enabling the nitridation of the gate dielectric layer 320 to be more uniform. The magnetic device 440 may be a permanent magnet or electromagnet etc. and the position of the magnetic device 440 may be shown as illustrated in FIG. 8, wherein it is located on the upper electrode 410, but is not limited thereto. Alternatively, the magnetic device 440 may be located on other positions, depending upon practical circumstances. The magnetic device 440 may be an independent controlled device, moving relative to the FinFET 300 (or the chamber of the plasma nitridation device 400), wherein the moving trajectory of the magnetic device 440 may be a rotational motion rotating with respect to the FinFET 300, a circular motion with the FinFET 300 as the center of a circle, a spiral motion, or a step-function motion etc.

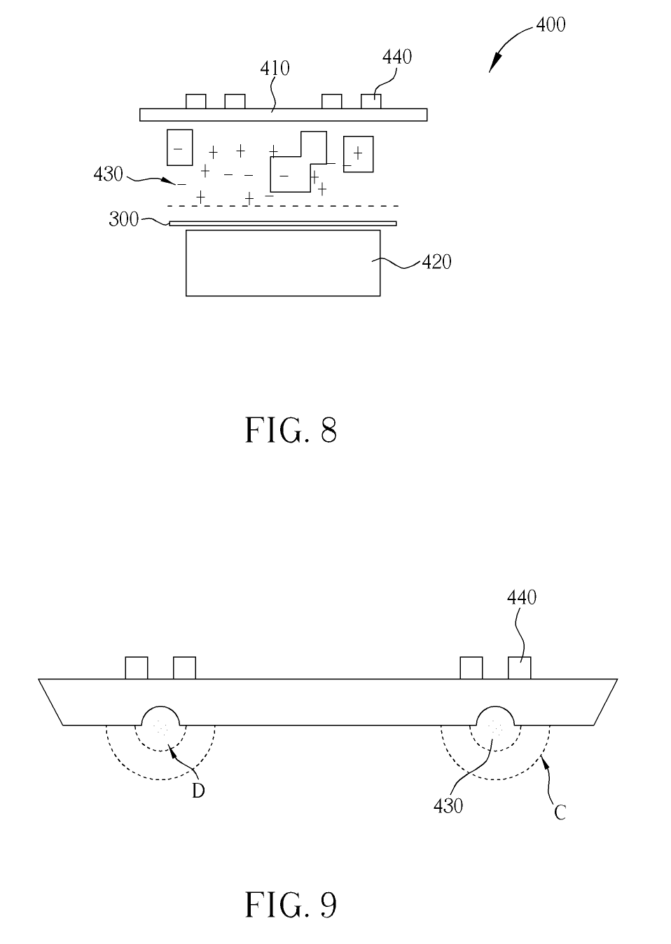

FIG. 9 schematically depicts a cross-sectional view of a portion of the plasma nitridation device of FIG. 8. As shown in FIG. 9, the magnetic device 440 can induce magnetic lines of force C, leading to local magnetic concentration and resulting in the nitrogen plasma 430 being concentrated in a predetermined area D and the portion of the gate dielectric layer 320 beneath D having a lower nitridation concentration to solve the problem of non-uniformity of nitridation. For instance, the vertical portions v1 and v2 of the gate dielectric layer 320 (as shown in FIG. 7) will easily have a lower nitridation concentration than the horizontal portion h of the gate dielectric layer 320, leading to the non-uniformity of the nitridation concentration of the gate dielectric layer 320. The magnetic device 440 can be disposed corresponding to the vertical portions v1 and v2, for increasing the nitridation concentration of the vertical portions v1 and v2. By applying the plasma nitridation device to a wafer (not shown), the inadequate nitridation in the edge of the water can also be solved. The magnetic device of the present invention can also be applied to other plasma doping processes, such as triethylborane doping process and phosphine doping process etc., but is not limited thereto.

The present invention provides a fabricating method of a MOS transistor and a fabricating method of a FinFET, which uniformly nitride the surface of the gate dielectric layer in a high concentration by performing a nitrogen plasma and helium gas containing nitridation process. For instance, the nitrogen plasma and helium gas containing nitridation process may be a decoupled plasma nitridation process, wherein a higher total pressure of gas is imported than in the prior art to achieve the aforementioned objective. Taking a FinFET as example, the nitridation concentration difference between the horizontal portion and the vertical portions of the FinFET formed by the present invention can be less than 3%, and even approach substantially the same nitridation concentration. Therefore, the problem of nitridation non-uniformity of the horizontal portion and the vertical portions associated with the prior art is solved. The present invention also provides a magnetic device, which can increase local nitridation concentration and improve the uniformity of the nitridation concentration of the surface of the gate dielectric layer.

Those skilled in the art will readily observe that numerous modifications and alterations of the device and method may be made while retaining the teachings of the invention.

What is claimed is:

1. A fabricating method of a MOS transistor, comprising:
providing a substrate;
forming a gate dielectric layer on the substrate; and
performing a nitrogen plasma and helium gas containing nitridation process to nitride the gate dielectric layer.

2. The fabricating method of a MOS transistor according to claim 1, wherein the nitridation process comprises a decoupled plasma nitridation process.

3. The fabricating method of a MOS transistor according to claim 2, wherein the total pressure of the gas imported during the decoupled plasma nitridation process is about 50 mT˜150 mT.

4. The fabricating method of a MOS transistor according to claim 3, wherein the total pressure of the gas imported during the decoupled plasma nitridation process is about 80 mT˜100 mT.

5. The fabricating method of a MOS transistor according to claim 1, wherein the nitridation process comprises remote plasma nitridation process.

6. The fabricating method of a MOS transistor according to claim 1, wherein the pressure ratio of nitrogen gas/helium gas imported during the nitridation process is not less than 5.

7. The fabricating method of a MOS transistor according to claim 1, wherein the pressure ratio of the nitrogen gas and the helium gas imported during the nitridation process is 5:1.

8. The fabricating method of a MOS transistor according to claim 1, wherein the pressure ratio of the nitrogen gas and the helium gas imported during the nitridation process is 10:1.

9. The fabricating method of a MOS transistor according to claim 1, wherein the gate dielectric layer comprises a silicon dioxide layer or a dielectric layer having a high dielectric constant.

10. The fabricating method of a MOS transistor according to claim 9, wherein the dielectric layer having a high dielectric constant comprises a hafnium oxide layer.

11. A fabricating method of a FinFET, comprising:
providing a substrate comprising at least a fin-shaped structure;
forming a gate dielectric layer having a [symbol] shaped profile on the fin-shaped structure; and
performing a nitrogen plasma and helium gas containing nitridation process to nitride the gate dielectric layer having a [symbol] shaped profile.

12. The fabricating method of a FinFET according to claim 11, wherein the nitridation process comprises a decoupled plasma nitridation process.

13. The fabricating method of a FinFET according to claim 12, wherein the total pressure of the gas imported during the decoupled plasma nitridation process is about 50 mT˜150 mT.

14. The fabricating method of a FinFET according to claim 12, wherein the total pressure of the gas imported during the decoupled plasma nitridation process is about 80 mT˜100 mT.

15. The fabricating method of a FinFET according to claim 11, wherein the nitridation process comprises remote plasma nitridation process.

16. The fabricating method of a FinFET according to claim 11, wherein the pressure ratio of nitrogen gas/helium gas imported during the nitridation process is not less than 5.

17. A FinFET structure, comprising:
a substrate having at least a fin-shaped structure; and
a gate dielectric layer having a [symbol] shaped profile located on the fin-shaped structure, wherein the gate dielectric layer having a [symbol] shaped profile comprises one horizontal portion and two vertical portion and the nitridation concentration difference between the horizontal portion and the vertical portion is less than 3%.

18. The FinFET structure according to claim 17, wherein the nitridation concentration of the horizontal portion and the vertical portion are substantially the same.

19. The FinFET structure according to claim 17, wherein the gate dielectric layer having a [symbol] shaped profile comprises a silicon dioxide layer and an oxynitride layer located on the external surface of the silicon dioxide layer.

20. The FinFET structure according to claim 17, wherein the gate dielectric layer having a [symbol] shaped profile comprises a hafnium oxide layer and a HfSiON layer located on the external surface of the hafnium oxide layer.
